(19) United States
(12) Patent Application Publication
(10) Pub. No.: US 2023/0377877 A1
(43) Pub. Date: Nov. 23, 2023

(54) METHODS AND SYSTEMS FOR FORMING MEMORY DEVICES AND COMPONENTS THEREOF

(71) Applicant: ASM IP Holding, B.V., Almere (NL)

(72) Inventors: Alessandra Leonhardt, Sipoo (FI); Matthew Surman, Helsinki (FI); Perttu Sippola, Tempe, AZ (US); Ranjith Karuparambil Ramachandran, Leuven (BE); Charles Dezelah, Helsinki (FI); Michael Givens, Oud-Heverlee (BE); Andrea Illiberi, Leuven (BE); Tatiana Ivanova, Helsinki (FI); Leo Lukose, Leuven (BE); Lorenzo Bottiglieri, Helsinki (FI); Suvidyakumar Vinod Homkar, Leuven (BE); Vivek Koladi Mootheri, Leuven (BE)

(21) Appl. No.: 18/319,933

(22) Filed: May 18, 2023

Related U.S. Application Data
(60) Provisional application No. 63/343,190, filed on May 18, 2022.

(51) Int. Cl. H01L 21/02; C23C 16/40; C23C 16/56; C23C 16/455

(52) U.S. Cl. CPC H01L 21/0228; H01L 21/02181; H01L 21/02189; H01L 21/02194; H01L 21/02318; C23C 16/405; C23C 16/56; C23C 16/45527; C23C 16/45553; H01L 29/0673

(57) ABSTRACT

Methods and related systems of processing a substrate. Described methods comprise executing a plurality of deposition cycles to form a doped hafnium zirconium oxide layer on the substrate.

### FIELD OF INVENTION

The present disclosure generally relates to the field of semiconductor processing methods and systems, and to the field integrated circuit manufacture. In particular, methods and systems suitable for forming memory elements and programmable logic devices.

### BACKGROUND OF THE DISCLOSURE

Ferroelectric devices have been proposed as memory elements. There is a need for improving the performance of ferroelectric memories.

Transistors having multiple threshold voltages are needed in modern integrated circuits. Ferroelectric layers have been proposed as gate dielectrics for metal-insulator-semiconductor field effect transistors (MISFETs) having a programmable threshold voltage. There is a need for improving the device performance of these transistors.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY OF THE DISCLOSURE

This summary may introduce a selection of concepts in a simplified form, which may be described in further detail below. This summary is not intended to necessarily identify key features or essential features of the claimed subject matter, nor is it intended to be used to limit the scope of the claimed subject matter.

Various embodiments of the present disclosure relate to ferroelectric memories, logic devices, related methods, related structures, and related systems.

Thus, provided is a method of processing a substrate. The method comprises providing a substrate to a processing chamber. The method further comprises executing a plurality of deposition cycles. A deposition cycle comprises a hafnium precursor pulse, a zirconium precursor pulse, an oxygen reactant pulse, and a dopant pulse. The hafnium precursor pulse comprises exposing the substrate to a hafnium precursor. The zirconium precursor pulse comprises exposing the substrate to a zirconium precursor. The oxygen reactant pulse comprises exposing the substrate to an oxygen reactant. The dopant pulse comprises exposing the substrate to a dopant precursor. The dopant precursor comprises a dopant element. Thus, a doped hafnium zirconium oxide layer is formed on the substrate.

In some embodiments, the dopant precursor pulse is carried out after the hafnium precursor pulse without any intervening oxygen reactant pulse.

In some embodiments, the dopant precursor pulse is carried out after the zirconium precursor pulse without any intervening oxygen reactant pulse.

In some embodiments, the dopant element comprises cerium.

In some embodiments, the dopant element comprises lanthanum.

In some embodiments, the dopant element is selected from the list consisting of tin, tellurium cerium, and lead.

In some embodiments, the dopant element is selected from the list consisting of ruthenium, palladium, rhenium, osmium, iridium, and platinum.

In some embodiments, dopant element is molybdenum or tungsten.

In some embodiments, the dopant element is Ru.

In some embodiments, the substrate comprises a surface layer. The hafnium zirconium oxide layer is formed on the surface layer. The surface layer comprises a surface layer conductive oxide. The surface layer conductive oxide comprises the dopant element and oxygen.

In some embodiments, executing the plurality of deposition cycles is preceded by a step of forming a surface layer. The surface layer comprises a surface layer conductive oxide. The surface layer conductive oxide comprises the dopant element and oxygen.

In some embodiments, the method further comprises a step of forming a top electrode on the hafnium zirconium oxide layer. The top electrode comprises a top conductive oxide, the top conductive oxide comprising the dopant element.

In some embodiments, the surface layer and the top conductive oxide have a substantially identical composition.

In some embodiments, at least one of the surface layer conductive oxide and the top conductive oxide comprise ruthenium oxide, and the dopant element comprises ruthenium.

In some embodiments, the step of forming a top electrode on the hafnium zirconium oxide layer is preceded by annealing the hafnium zirconium oxide layer.

In some embodiments, the method is carried out in a system that comprises a processing chamber. In such embodiments, the step of executing a plurality of deposition cycles and the step of annealing the hafnium zirconium oxide layer can be carried out in first processing chamber.

In some embodiments, the method is carried out in a system that comprises a first processing chamber and a second processing chamber. In such embodiments, the step of executing a plurality of deposition cycles and the step of annealing the hafnium zirconium oxide layer can be carried out in the first processing chamber, and the step of forming the top electrode can be carried out in the second processing chamber.

In some embodiments, the method can be carried out in a system that comprises a first processing chamber, a second processing chamber, and a third processing chamber. In such embodiments, the step of executing a plurality of deposition cycles can be carried out in the first processing chamber, the step of annealing the hafnium zirconium oxide layer can be carried out in the second processing chamber, and the step of forming the top electrode can be carried out in the third processing chamber.

Further described herein is a system that comprises one or more processing chambers, a hafnium precursor source that comprises a hafnium precursor, a zirconium precursor source that comprises a zirconium precursor, a dopant precursor source that comprises a dopant precursor; an oxygen reactant source comprising an oxygen reactant; and, a controller. The controller is configured to control gas flow into the one or more processing chambers and to cause the system to process a substrate by means of a method as described herein.

Further described herein is a method of processing a substrate, the method comprising: providing the substrate to a processing chamber; executing a plurality of deposition cycles, wherein a deposition cycle comprises a hafnium precursor pulse, a zirconium precursor pulse, an oxygen reactant pulse, and a dopant pulse; wherein the hafnium precursor pulse comprises exposing the substrate to a hafnium precursor; wherein the zirconium precursor pulse comprises exposing the substrate to a zirconium precursor; wherein the oxygen reactant pulse comprises exposing the substrate to an oxygen reactant; wherein the first dopant pulse comprises exposing the substrate to a first dopant precursor, the first dopant precursor comprising a first dopant element; thereby forming a doped hafnium zirconium oxide layer on the substrate; wherein the first dopant precursor pulse is carried out after one of the hafnium precursor pulse and the zirconium precursor pulse without any intervening oxygen reactant pulse.

In some embodiments, the deposition cycle further comprises a second dopant pulse that comprises exposing the substrate to a second dopant precursor, the second dopant precursor comprising a second dopant element, the second dopant element being different from the first dopant element.

In some embodiments, the dopant precursor pulse is carried out after the hafnium precursor pulse without any intervening oxygen reactant pulse.

In some embodiments, the dopant precursor pulse is carried out after the zirconium precursor pulse without any intervening oxygen reactant pulse.

In some embodiments, at least one of the first dopant element and the second dopant element comprises cerium.

In some embodiments, the first dopant element comprises lanthanum.

In some embodiments, the first dopant element is selected from the list consisting of tin, tellurium, cerium, and lead.

In some embodiments, first dopant element is selected from the list consisting of ruthenium, palladium, rhenium, osmium, iridium, and platinum.

In some embodiments, the first dopant element is molybdenum or tungsten.

In some embodiments, the first dopant element is Ru.

8. The method according to any one of claims 2 to 5 wherein the second dopant element is independently from the first dopant selected from the list consisting of cerium, lanthanum, tin, tellurium, lead, ruthenium, palladium, rhenium, osmium, iridium, platinum, molybdenum, and tungsten.

In some embodiments, at least one of the first dopant precursor and the second dopant precursor are independently selected from a compound that can be represented by the formula M(RCp)x(L)y wherein M is a rare earth metal, wherein R is selected from H, Me, Et, iPr, and tBu, and wherein L is selected from N,N′-diisopropylacetamidinate, N,N′-di-tert-butylacetamidinate, N,N′-diisopropylformamidinate, and N,N′-di-tert-butylformamidinate.

In some embodiments, the substrate comprises a surface layer, wherein the hafnium zirconium oxide layer is formed on the surface layer, wherein the surface layer comprises a surface layer conductive oxide, wherein the surface layer conductive oxide comprises the dopant element and oxygen.

In some embodiments, executing the plurality of deposition cycles is preceded by a step of forming a surface layer, the surface layer comprising a surface layer conductive oxide, wherein the surface layer conductive oxide comprises the dopant element and oxygen.

In some embodiments, the method further comprises a step of forming a top electrode on the hafnium zirconium oxide layer, the top electrode comprising a top conductive oxide, the top conductive oxide comprising the dopant element.

In some embodiments, the surface layer and the top conductive oxide have a substantially identical composition.

In some embodiments, at least one of the surface layer conductive oxide and the top conductive oxide comprise ruthenium oxide, and wherein the dopant element comprises ruthenium.

In some embodiments, the step of forming a top electrode on the hafnium zirconium oxide layer is preceded by annealing the hafnium zirconium oxide layer.

In some embodiments, the method is carried out in a system comprising a processing chamber, wherein the step of executing a plurality of deposition cycles and the step of annealing the hafnium zirconium oxide layer are carried out in first processing chamber.

In some embodiments, the method is carried out in a system comprising a first processing chamber and a second processing chamber, wherein the step of executing a plurality of deposition cycles and the step of annealing the hafnium zirconium oxide layer are carried out in the first processing chamber, and wherein the step of forming the top electrode is carried out in the second processing chamber.

In some embodiments, the method is carried out in a system comprising a first processing chamber, a second processing chamber, and a third processing chamber, wherein the step of executing a plurality of deposition cycles is carried out in the first processing chamber, wherein the step of annealing the hafnium zirconium oxide layer is carried out in the second processing chamber, and wherein the step of forming the top electrode is carried out in the third processing chamber.

Further described herein is a system that comprises one or more processing chambers; a hafnium precursor source comprising a hafnium precursor; a zirconium precursor source comprising a zirconium precursor; a first dopant precursor source comprising a first dopant precursor, a second dopant precursor source comprising a second dopant precursor; an oxygen reactant source comprising an oxygen reactant; and, a controller, wherein the controller is configured to control gas flow into the one or more processing chambers and to process a substrate by means of a method as described herein.

Further described herein is a precursor source comprised in a system as described herein, the precursor source comprising a precursor selected from a hafnium precursor, a zirconium precursor, a first dopant precursor, and a second dopant precursor. Further described herein is a method of filling a precursor source that is operationally connectable to a system as described herein, the method comprising: providing the precursor source; and, filling the precursor source with a precursor selected from a hafnium precursor, a zirconium precursor, a first dopant precursor, and a second dopant precursor.

These and other embodiments will become readily apparent to those skilled in the art from the following detailed description of certain embodiments having reference to the attached figures. The invention is not limited to any particular embodiments disclosed.

### BRIEF DESCRIPTION OF THE DRAWING FIGURES

A more complete understanding of the embodiments of the present disclosure may be derived by referring to the detailed description and claims when considered in connection with the following illustrative figures.

FIG. 1 shows an embodiment of a method as described. The method comprises a step (111) of providing a substrate to a first processing chamber.

FIGS. 2 to 6 schematically shows process flows of embodiments of methods as described herein.

FIG. 7 illustrates a system (700) in accordance with exemplary embodiments of the disclosure.

FIG. 8 shows experimental results obtained using an embodiment of a method as described herein.

FIG. 9 illustrates a structure (900) in accordance with examples of the disclosure.

FIG. 10 illustrates an exemplary capacitor (1000).

FIG. 11 schematically shows a system (1100) comprising a first process chamber (1110), a second process chamber (1120), and a third process chamber (1130).

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

The description of exemplary embodiments of methods, structures, devices and systems provided below is merely exemplary and is intended for purposes of illustration only; the following description is not intended to limit the scope of the disclosure or the claims. Moreover, recitation of multiple embodiments having stated features is not intended to exclude other embodiments having additional features or other embodiments incorporating different combinations of the stated features. For example, various embodiments are set forth as exemplary embodiments and may be recited in the dependent claims. Unless otherwise noted, the exemplary embodiments or components thereof may be combined or may be applied separate from each other.

In this disclosure, “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, other gas distribution device, or the like, can be used for, e.g., sealing the reaction space, and can include a seal gas. Precursors and reactants can be gasses. Exemplary seal gasses include noble gasses, nitrogen, and the like. In some cases, the term “precursor” can refer to a compound that participates in the chemical reaction that produces another compound, and particularly to a compound that constitutes a film matrix or a main skeleton of a film; the term “reactant” can be used interchangeably with the term precursor.

As used herein, the term “substrate” can refer to any underlying material or materials that can be used to form, or upon which, a device, a circuit, or a film can be formed by means of a method according to an embodiment of the present disclosure. A substrate can include a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. Further, the substrate can include various features, such as recesses, protrusions, and the like formed within or on at least a portion of a layer of the substrate. By way of example, a substrate can include bulk semiconductor material and an insulating or dielectric material layer overlying at least a portion of the bulk semiconductor material. Further, the term “substrate” may refer to any underlying material or materials that may be used, or upon which, a device, a circuit, or a film may be formed. The “substrate” may be continuous or non-continuous; rigid or flexible; solid or porous. The substrate may be in any form such as a powder, a plate, or a workpiece. Substrates in the form of a plate may include wafers in various shapes and sizes. Substrates may be made from materials, such as silicon, silicon germanium, silicon oxide, gallium arsenide, gallium nitride and silicon carbide for example. A continuous substrate may extend beyond the bounds of a process chamber where a deposition process occurs and may move through the process chamber such that the process continues until the end of the substrate is reached. A continuous substrate may be supplied from a continuous substrate feeding system allowing for manufacture and output of the continuous substrate in any appropriate form. Non-limiting examples of a continuous substrate may include a sheet, a non-woven film, a roll, a foil, a web, a flexible material, a bundle of continuous filaments or fibers (i.e. ceramic fibers or polymer fibers). Continuous substrates may also comprise carriers or sheets upon which non-continuous substrates are mounted.

As used herein, the term “film” and/or “layer” can refer to any continuous or non-continuous structure and material, such as material deposited by the methods disclosed herein. For example, a film and/or layer can include two-dimensional materials, three-dimensional materials, nanoparticles, partial or full molecular layers or partial or full atomic layers or clusters of atoms and/or molecules. A film or layer may comprise, or may consist at least partially of, a plurality of dispersed atoms on a surface of a substrate and/or may be or may become embedded in a substrate and/or may be or may become embedded in a device manufactured on that substrate. A film or layer may comprise material or a layer with pinholes and/or isolated islands. A film or layer may be at least partially continuous. A film or layer may be patterned, e.g. subdivided, and may be comprised in a plurality of semiconductor devices. A film or layer may be selectively grown on some parts of a substrate, and not on others.

The term “deposition process” as used herein can refer to the introduction of precursors (and/or reactants) into a reaction chamber to deposit a layer over a substrate. “Cyclical deposition processes” are examples of “deposition processes”.

The term “cyclic deposition process” or “cyclical deposition process” can refer to the sequential introduction of precursors (and/or reactants) into a reaction chamber to deposit a layer over a substrate and includes processing techniques such as atomic layer deposition (ALD), cyclical chemical vapor deposition (cyclical CVD), and hybrid cyclical deposition processes that include an ALD component and a cyclical CVD component.

The term “atomic layer deposition” can refer to a vapor deposition process in which deposition cycles, typically a plurality of consecutive deposition cycles, are conducted in a process chamber. The term atomic layer deposition, as used herein, is also meant to include processes designated by related terms, such as chemical vapor atomic layer deposition, atomic layer epitaxy (ALE), molecular beam epitaxy (MBE), gas source MBE, organometallic MBE, and chemical beam epitaxy, when performed with alternating pulses of precursor(s)/reactive gas(es), and purge (e.g., inert carrier) gas(es). A pulse can comprise exposing a substrate to a precursor or reactant. This can be done, for example, by introducing a precursor or reactant to a reaction chamber in which the substrate is present. Additionally or alternatively, exposing the substrate to a precursor can comprise moving the substrate to a location in a substrate processing system in which the reactant or precursor is present.

Generally, for ALD processes, during each cycle, a precursor is introduced into a reaction chamber and is chemisorbed onto a deposition surface (e.g., a substrate surface that can include a previously deposited material from a previous ALD cycle or other material) and forming about a monolayer or sub-monolayer of material that does not readily react with additional precursor (i.e., a self-limiting reaction). Thereafter, a reactant (e.g., another precursor or reaction gas) may subsequently be introduced into the process chamber for use in converting the chemisorbed precursor to the desired material on the deposition surface. The reactant can be capable of further reaction with the precursor. Purging steps can be utilized during one or more cycles, e.g., during each step of each cycle, to remove any excess precursor from the process chamber and/or remove any excess reactant and/or reaction byproducts from the reaction chamber.

As used herein, the term “purge” may refer to a procedure in which an inert or substantially inert gas is provided to a reaction chamber in between two pulses of gasses that react with each other. For example, a purge, e.g. using a noble gas, may be provided between a precursor pulse and a reactant pulse, thus avoiding or at least minimizing gas phase interactions between the precursor and the reactant. It shall be understood that a purge can be effected either in time or in space, or both. For example in the case of temporal purges, a purge step can be used e.g. in the temporal sequence of providing a first precursor to a reaction chamber, providing a purge gas to the reaction chamber, and providing a second precursor to the reaction chamber, wherein the substrate on which a layer is deposited does not move. For example in the case of spatial purges, a purge step can take the following form: moving a substrate from a first location to which a first precursor is continually supplied, through a purge gas curtain, to a second location to which a second precursor is continually supplied.

It shall be understood that pulses can be effected either in time or in space, or both. For example, in the case of temporal pulses, a precursor can be provided for a pre-determined amount of time before and after which an inert gas is provided to the reaction chamber. For example, in the case of spatial pulses, a substrate can be moved through a pre-determined location at which precursor is provided and which is surrounded by one or more inert purge gas curtains.

As used herein, a “precursor” includes a gas or a material that can become gaseous and that can be represented by a chemical formula that includes an element which may be incorporated during a deposition process as described herein.

The term “oxygen reactant” can refer to a gas or a material that can become gaseous and that can be represented by a chemical formula that includes oxygen. In some cases, the chemical formula includes oxygen and hydrogen.

Further, in this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like.

As used herein, the term “comprising” indicates that certain features are included, but that it does not exclude the presence of other features, as long as they do not render the claim or embodiment unworkable. In some embodiments, the term “comprising” includes “consisting”. As used herein, the term “consisting” indicates that no further features are present in the apparatus/method/product apart from the ones following said term. When the term “consisting” is used referring to a chemical compound, it indicates that the chemical compound only contains the components which are listed.

In this disclosure, any defined meanings do not necessarily exclude ordinary and customary meanings, in some embodiments.

Described herein is a method of processing a substrate. The method comprises providing a substrate to a processing chamber. The method further comprises executing a plurality of deposition cycles. A deposition cycle comprises a precursor pulse and an oxygen reactant pulse. The precursor pulse comprises exposing the substrate to a precursor. The oxygen reactant pulse comprises exposing the substrate to an oxygen reactant. Thus, a layer is formed on the substrate. In some embodiments, the layer comprises a high-k material such as hafnium oxide, zirconium oxide, or a binary oxide such as hafnium zirconium oxide. In some embodiments, the hafnium zirconium oxide is non-stoichiometric. In some embodiments, the hafnium oxide contains hafnium and zirconium in a 2:1, in a 1:1, or in a 1:2 ratio. In some embodiments, the layer comprises an antiferroelectric layer that is formed on the substrate. In some embodiments, the layer comprises a ferroelectric layer that is formed on the substrate. The ferroelectric layer can suitably have a fluorite structure.

Described herein is a method of processing a substrate. The method comprises providing a substrate to a processing chamber. The method further comprises executing a plurality of deposition cycles. A deposition cycle comprises a hafnium precursor pulse and an oxygen reactant pulse. The hafnium precursor pulse comprises exposing the substrate to a hafnium precursor. The oxygen reactant pulse comprises exposing the substrate to an oxygen reactant. Thus, a hafnium oxide layer is formed on the substrate. The hafnium oxide can suitably have a fluorite structure.

Described herein is a method of processing a substrate. The method comprises providing a substrate to a processing chamber. The method further comprises executing a plurality of deposition cycles. A deposition cycle comprises a hafnium precursor pulse, a zirconium precursor pulse, and an oxygen reactant pulse. The hafnium precursor pulse comprises exposing the substrate to a hafnium precursor. The zirconium precursor pulse comprises exposing the substrate to a zirconium precursor. The oxygen reactant pulse comprises exposing the substrate to an oxygen reactant. Thus, a hafnium zirconium oxide layer is formed on the substrate. The hafnium zirconium oxide can suitably have a fluorite structure. Suitably, the precursors and the reactants can be gaseous.

In some embodiments, a method as described herein can be employed to form one or more constituent parts of a ferroelectric random access memory, a ferroelectric field effect transistor, and a ferroelectric tunnel junction.

In some embodiments, a deposition cycle further comprises a dopant pulse. The dopant pulse comprises exposing the substrate to a dopant precursor. The dopant precursor comprises a dopant element. Thus, a doped ferroelectric layer, such as a doped hafnium oxide layer or a doped hafnium zirconium oxide layer, is formed on the substrate. It shall be understood that hafnium zirconium oxide can refer to a material comprising hafnium, zirconium, and oxygen. Hafnium zirconium oxide can further comprise other elements, such as a dopant. Hafnium zirconium oxide comprising a dopant element can be referred to as doped hafnium zirconium oxide.

Thus, further described herein is a method of processing a substrate. The method comprises providing the substrate to a processing chamber. The method further comprises executing a plurality of deposition cycles. A deposition cycle comprises a hafnium precursor pulse, a zirconium precursor pulse, an oxygen reactant pulse, and a dopant precursor pulse. The hafnium precursor pulse comprises exposing the substrate to a hafnium precursor. The zirconium precursor pulse comprises exposing the substrate to a zirconium precursor. The oxygen reactant pulse comprises exposing the substrate to an oxygen reactant. The dopant precursor comprises a dopant element. Thus, a doped hafnium zirconium oxide layer is formed on the substrate.

Advantageously, hafnium zirconium oxide layers formed using embodiments of methods as described herein can have a low amount of wakeup cycles, good endurance, and high remnant polarization (2Pr).

The dopant precursor pulse can, in some embodiments, be carried out after one of the hafnium precursor pulse and the zirconium precursor pulse without any intervening oxygen reactant pulse. In some embodiments, the dopant precursor pulse is carried out after the hafnium precursor pulse without any intervening oxygen reactant pulse. In some embodiments, the dopant precursor pulse is carried out after the zirconium precursor pulse without any intervening oxygen reactant pulse.

In some embodiments, an atomic layer deposition process, or other cyclical deposition process, of forming a doped ferroelectric layer such as a doped hafnium zirconium oxide layer, can thus be represented using the following formula:

N[x(B₁+A₁)+y(B₂+A₂)+z(C)], (i)

in which N is the number of deposition cycles, x is the number of first metal sub-cycles per deposition cycle, y is the number of second metal sub cycles per deposition cycles, z is the number of dopant pulses per deposition cycle, B₁ denotes a pulse of a first oxygen reactant, B₂ denotes a pulse of a second oxygen reactant, A₁ denotes a pulse of a first metal precursor, A₂ denotes a pulse of a second metal precursor, and C denotes a pulse of a dopant precursor. Thus, formula (i) indicates that the cyclical deposition process in question comprises N super cycles, and that a super cycle comprises x subsequent first metal sub-cycles, followed by y subsequent second metal sub-cycles, followed by z dopant precursor pulses.

In some embodiments, a first metal sub-cycle comprises a first oxygen reactant pulse followed by a first metal precursor pulse. Alternatively, a first metal sub-cycle can comprise a first metal precursor pulse followed by a first oxygen reactant pulse.

In some embodiments, a second metal sub-cycle comprises a second oxygen reactant pulse followed by a second metal precursor pulse. Alternatively, a second metal sub-cycle can comprise a second metal precursor pulse followed by a second oxygen reactant pulse.

Suitably, the first oxygen reactant pulse comprises exposing a substrate to a first oxygen reactant, a second oxygen reactant comprises exposing the substrate to a second oxygen reactant, a first metal precursor pulse comprises exposing the substrate to a first metal precursor, a second metal precursor pulse comprises exposing the substrate to a second metal precursor, and a dopant precursor pulse comprises exposing the substrate to a dopant precursor. Suitably, the first and second oxygen reactants can comprise an oxygen reactant as described herein. The first and second oxygen reactants can be the same or different. Suitably, the first metal precursor can comprise a hafnium precursor as described herein. Suitably, the second metal precursor can comprise a zirconium precursor as described herein. Suitably, the dopant precursor comprises a dopant element as described herein.

In some embodiments, an atomic layer deposition process, or other cyclical deposition process, of forming a doped ferroelectric layer such as a doped hafnium zirconium oxide layer can be represented using the following formula:

N[y(B₂+A₂)+x(B₁+A₁)+z(C)], (ii)

which is similar to the process represented by formula (i), except that the second metal sub-cycle precedes the first metal sub-cycle.

In some embodiments, an atomic layer deposition process, or other cyclical deposition process, of forming a doped ferroelectric layer such as a doped hafnium zirconium oxide layer can be represented using the following formula:

N[y(B₂+A₂)+z(C)+x(B₁+A₁)], (iii)

which is similar to the process represented by formula (i), except that the second metal sub-cycles precede the first metal sub-cycles, and the dopant precursor pulses are executed in between the second metal sub-cycles and the first metal sub-cycles.

Of course, other permutations are possible as well. For example, the dopant precursor pulses can precede the second metal sub-cycles and the second metal sub-cycles can precede the first metal sub-cycles. As another possible permutation, a number z₁ of the dopant precursor pulses can be carried out after the first metal sub-cycles and a number z₂ of the dopant precursor pulses can be carried out after the second metal sub-cycles.

Advantageously, atomic layer deposition processes or other cyclical deposition processes according to any one of formulas (i), (ii), or (iii), can result in decreased dopant incorporation in doped ferroelectric layers such as doped hafnium zirconium oxide layers formed using embodiments of the methods as described herein, when compared to processes which employ an oxygen reactant pulse after every metal precursor pulse.

In some embodiments, a method as described herein can comprise forming a doped hafnium zirconium oxide layer comprising two or more different dopant elements. In particular, and in some embodiments, an atomic layer deposition process, or other cyclical deposition process, of forming a doped ferroelectric layer such as a doped hafnium zirconium oxide layer can be represented using one or more of the following formulas:

N[y(B₂+A₂)+z(C₁)+x(B₁+A₁)+α(C₂)], (iv)

and

N[x(B₁+A₁)+z(C₁)+y(B₂+A₂)+α(C₂)]. (v)

In which the formula and symbols are defined analogously as before. Further, it shall be understood that in formulas iv and v, z indicates a number of first dopant precursor pulses that are sequentially carried out, α indicates the number of second dopant precursor pulses that are sequentially carried out, C₁ denotes a first dopant precursor pulse, and C₂ denotes a second dopant precursor pulse.

In some embodiments, the parameters x, y, z, and α can be independently selected from an integer from at least 1 to at most 100, or from at least 2 to at most 50, or from at least 5 to at most 20, or from at least 10 to at most 15. In some embodiments, N is from at least 2 to at most 10000, or from at least 5 to at most 20, or from at least 20 to at most 100, or from at least 100 to at most 500, or from at least 500 to at most 2000, or from at least 2000 to at most 5000, or from at least 5000 to at most 10000. In some embodiments, x, y, z, and α are 1.

In some embodiments, the dopant element is capable of forming an oxide having a fluorite crystal structure. Suitable dopant elements that are capable of forming an oxide having a fluorite crystal structure include tin, tellurium cerium, lead, ruthenium, palladium, rhenium, osmium, iridium, platinum, molybdenum, and tungsten. Thus, such dopant elements are capable of adopting at least one of an MO₂ and an MF₂ structure.

In some embodiments, the dopant element has an ionic radius which is bigger than the atomic radius of Zr. In some embodiments, the dopant element has a preferred oxidation state of +4. In some embodiments, the dopant element has an ionic radius which is bigger than the ionic radius of Zr for the same ionization degree. For example, the dopant element can have a bigger ionic radios than Zr when the ionization degree is +1, +2, or +3 elementary charges. In some embodiments, the dopant element has a preferred oxidation state of +4 and the dopant element has an ionic radius which is bigger than the ionic radius of Zr for the same ionization degree.

In some embodiments, the dopant element comprises cerium.

In some embodiments, the dopant element comprises lanthanum.

In some embodiments, the dopant element is selected from the list consisting of tin, tellurium cerium, and lead.

In some embodiments, the dopant element is strontium.

In some embodiments, the dopant element is selected from the list consisting of ruthenium, palladium, rhenium, osmium, iridium, and platinum.

In some embodiments, the dopant element is molybdenum or tungsten.

In some embodiments, dopant element is ruthenium (Ru).

In some embodiments, a doped ferroelectric layer such as a doped hafnium zirconium oxide can comprise two or more dopants. For example, the two or more dopants can comprise two or more dopant elements selected from the list consisting of tin, tellurium, cerium, lead, strontium, ruthenium, palladium, rhenium, osmium, iridium, platinum, molybdenum, and tungsten. For example, the two or more dopants can comprise ruthenium and strontium. Such doped ferroelectric layers can be formed by executing a plurality of deposition cycles wherein ones from the plurality of deposition cycles comprise executing two different dopant precursors, a first dopant precursor and a second dopant precursor, wherein the first dopant pulse comprises exposing the substrate to a first dopant precursor, the first dopant precursor comprising a first dopant element, and wherein the second dopant pulse comprises exposing the substrate to a second dopant precursor, the second dopant precursor comprising a second dopant element that is different from the first dopant element. The first dopant element and the second dopant element can be independently selected from tin, tellurium, cerium, lead, strontium, ruthenium, palladium, rhenium, osmium, iridium, platinum, molybdenum, and tungsten.

In some embodiments, a method as described herein employs a substrate that comprises a surface layer.

In some embodiments, the surface layer comprises a transition metal nitride such as TiN. In some embodiments, the surface layer comprises a transition metal such as W or Mo.

In some embodiments, the surface layer comprises a conductive oxide, i.e. a surface layer conductive oxide. In some embodiments, the surface layer conductive oxide comprises the dopant element. In some embodiments, the surface layer conductive oxide comprises the dopant element and oxygen. In other words, the substrate can comprise a bottom electrode comprising a surface layer conductive oxide comprising the dopant element and oxygen.

In some embodiments, a method as described herein includes a step of forming a surface layer on the substrate before executing the plurality of deposition cycles. A surface layer can alternatively be called a bottom electrode. The surface layer comprises a surface layer conductive oxide. In some embodiments, the surface layer conductive oxide comprises the dopant element. In some embodiments, the surface layer conductive oxide comprises the dopant element and oxygen. Thus, a bottom electrode can be formed on the substrate.

In some embodiments, at least one of the bottom electrode and the top electrode comprises ruthenium oxide (RuO₂). Advantageously, and without the present invention being bound by any particular theory or mode of operation, it is believed that ruthenium oxide electrodes can advantageously promote the crystallization of a layer, e.g. ferroelectric layer, having a fluorite structure, e.g. hafnium zirconium oxide, at low temperature by acting as a fluorite template. Additionally or alternatively, ruthenium oxide electrodes can reduce the leakage current due to their high work function and low oxygen scavenging potential. Additionally or alternatively, ruthenium oxide electrodes can have a non-existent or negligible contribution to equivalent oxide thickness since RuO₂ is a conductive electrode.

In some embodiments, the dopant element comprises ruthenium, and at least one of the bottom electrode and the top electrode comprise ruthenium oxide (RuO₂).

In some embodiments, the bottom electrode comprises a bilayer comprising a ruthenium layer and a ruthenium oxide layer.

In some embodiments, at least one of the bottom electrode and the top electrode comprises ruthenium, strontium, and oxygen. For example, at least one of the bottom electrode and the top electrode can comprise a strontium ruthenate such as monostrontium ruthenate. Advantageously, such electrodes have a high work function which can advantageously reduce the leakage current of ferroelectric capacitors comprising such an electrode.

In some embodiments, at least one of the bottom electrode and the top electrode comprises ruthenium, strontium, and oxygen; and the ferroelectric layer comprises strontium, ruthenium, or both. For example, the bottom electrode can comprise monostrontium ruthenate and the ferroelectric layer can comprise hafnium zirconium oxide doped with ruthenium, strontium, or both.

In some embodiments, a method as described herein further comprises a step of forming a top electrode on the ferroelectric layer. For example, the ferroelectric layer can comprise a doped or undoped hafnium zirconium oxide layer. The top electrode comprises a top conductive oxide. The top conductive oxide comprises the dopant element. Employing at least one of a conductive bottom electrode and a conductive top electrode can improve the ferroelectric properties of doped or undoped HfZrO₂ when compared to typical electrodes such as TiN or W which can suffer from high oxygen scavenging potential and a moderate work function. In addition, it can be difficult, impractical, or even impossible to deposit such typical electrodes in the same reactor as the ferroelectric layer, thereby necessitating the use of two reactors, which can result in elevated costs. This notwithstanding, and in some embodiments, the top electrode can comprise a transition metal nitride such as TiN. In some embodiments, the top electrode can comprise a transition metal such as W or Mo.

Suitable conductive oxides include semiconducting oxides. The semiconducting oxides can be degenerate or non-degenerate. The semiconducting oxides can exhibit n-type conductivity or p-type conductivity. In some embodiments, the semiconducting oxide comprises doped or undoped indium-gallium-zinc-oxide. In some embodiments, the semiconducting oxide is selected from the list consisting of vanadium oxide, indium oxide, and indium tin oxide. It shall be understood that indium gallium zinc oxide can refer to a material comprising gallium, zinc, indium, oxygen, and optionally further elements such as dopant elements. It shall be understood that indium tin oxide can refer to a material comprising indium, tin, oxygen, and optionally further elements such as dopant elements.

In some embodiments, at least one of the surface layer conductive oxide and the top conductive oxide comprise ruthenium oxide. In such embodiments, the dopant element can, in some embodiments, comprise ruthenium.

In some embodiments, the surface layer and the top conductive oxide have a substantially identical composition.

In some embodiments, at least one of the surface layer and the top conductive oxide comprise ruthenium oxide. Thus, in some embodiments, the surface layer comprises ruthenium oxide; in some embodiments, the top conductive oxide comprises ruthenium oxide; and, in some embodiments, the surface layer and the top conductive oxide comprise ruthenium oxide. Accordingly, a ferroelectric layer such as a doped or undoped hafnium zirconium oxide layer sandwiched between two ruthenium oxide electrodes can be manufactured. Advantageously, the surface layer, the ferroelectric layer, and the top conductive electrode can be sequentially formed in the same vacuum system, without any intervening vacuum break.

It shall be understood that the terms “top” and “bottom” do not necessarily refer to a physical position, but can be used to simply refer to one or another feature, structure, layer, or method step. In some embodiments, the terms “top” and “bottom” can be replaced by other terms such as “first” and “second”.

In some embodiments, the surface layer, the ferroelectric layer, and the top conductive electrode can be formed in one and the same reaction chamber.

Alternatively, at least one of the surface layer and the top conductive electrode can be formed in a first reaction chamber, and the ferroelectric layer can be formed in a second reaction chamber. It shall be understood that the first reaction chamber and the second reaction chamber are comprised in the same vacuum system, that substrate transport between the reaction chambers can occur by means of a robot arm or other means, and that vacuum is not broken during transport between the first and second reaction chambers.

When at least one of the surface layer and the top conductive oxide comprise ruthenium oxide, the dopant element can suitably comprise ruthenium as well.

In some embodiments, the step of forming a top electrode on the ferroelectric layer is preceded by annealing the ferroelectric layer. Accordingly, the material quality of a ferroelectric layer can be improved without subjecting the top electrode to the same heat treatment.

In some embodiments, the step of executing a plurality of deposition cycles and the step of annealing the ferroelectric layer are carried out in the same processing chamber. Doing so can advantageously enhance at least one of throughput and material quality.

In some embodiments, a method as described herein is carried out in a system comprising a first processing chamber and a second processing chamber. In such embodiments, the step of executing a plurality of deposition cycles and the step of annealing the ferroelectric layer can be carried out in the first processing chamber, and the step of forming the top electrode can be carried out in the second processing chamber.

In some embodiments, a method as described herein is carried out in a system that comprises a first processing chamber, a second processing chamber, and a third processing chamber. In such embodiments, the step of executing a plurality of deposition cycles can be carried out in the first processing chamber, the step of annealing the ferroelectric layer can be carried out in the second processing chamber, and the step of forming the top electrode can be carried out in the third processing chamber. Optionally, a bottom electrode can also be formed in the third processing chamber, or in a fourth processing chamber. Suitably, the bottom electrode can be formed prior to formation of the ferroelectric layer. Suitably, the system can comprise a robotic transport system that is arranged to transport substrates from one of the first processing chamber, the second processing chamber, and the third processing chamber to another processing chamber selected from the first processing chamber, the second processing chamber, and the third processing chamber, without any intervening vacuum break.

In some embodiments, the hafnium precursor comprises Hafnium in a +4 oxidation state.

In some embodiments, the hafnium precursor comprises one or more ligands selected from alkylamido ligands, alkoxy ligands, cyclopentadienyl ligands, beta-diketonate ligands, alkyl ligands, amidinate ligands, and halide ligands.

In some embodiments, the hafnium precursor can comprise at least one of an alkylamido ligand and an dialkylamido ligand. Suitable hafnium alkylamines include tetrakis(dimethylamino)hafnium, tetrakis(diethylamino)hafnium, and tetrakis(ethylmethylamino)hafnium.

In some embodiments, the hafnium precursor comprises a hafnium halide such as a hafnium chloride, a hafnium bromide, or a hafnium iodide. Suitable hafnium chlorides include HfCl₄. Suitable hafnium bromides include HfBr₄. Suitable hafnium iodides include HfI₄.

In some embodiments, the hafnium precursor comprises a heteroleptic hafnium precursor. In some embodiments, the heteroleptic hafnium precursor comprises an unsubstituted or an alkyl-substituted hafnium cyclopentadienyl ligand. In some embodiments, the hafnium precursor comprises one or more alkylamido ligands. In some embodiments, the hafnium precursor comprises an alkylamido ligand and an unsubstituted or an alkyl-substituted cyclopentadienyl ligand. Suitable hafnium precursors include HfCp(NMe₂)₃, i.e. Tris(dimethylamino)cyclopentadienyl Hafnium.

In some embodiments, the zirconium precursor comprises Zirconium in a +4 oxidation state.

In some embodiments, the zirconium precursor comprises one or more ligands selected from the list consisting of alkylamido ligands, alkoxy ligands, cyclopentadienyl ligands, alkylcyclopetadienyl ligands, beta-diketonate ligands, alkyl ligands, amidinate ligands, and halide ligands.

In some embodiments, the zirconium precursor can comprise at least one of an alkylamido ligand and an dialkylamido ligand. Suitable zirconium alkylamines include tetrakis(dimethylamino)zirconium, tetrakis(diethylamino)zirconium, and tetrakis(ethylmethylamino)zirconium.

In some embodiments, the zirconium precursor comprises a heteroleptic zirconium precursor. In some embodiments, the heteroleptic zirconium precursor comprises an unsubstituted or an alkyl-substituted zirconium cyclopentadienyl ligand. In some embodiments, the zirconium precursor comprises one or more alkylamido ligands. In some embodiments, the zirconium precursor comprises an alkylamido ligand and an unsubstituted or an alkyl-substituted cyclopentadienyl ligand. Suitable zirconium precursors include HfCp(NMe₂)₃, i.e. Tris(dimethylamino)cyclopentadienyl Zirconium.

In some embodiments, the dopant precursor comprises a dopant element in a +4 oxidation state. In some embodiments, the first dopant precursor comprises a dopant element in a +4 oxidation state. In some embodiments, the second dopant precursor comprises a dopant element in a +4 oxidation state. In some embodiments, the hafnium precursor comprises hafnium in a +4 oxidation state, the zirconium precursor comprises zirconium in a +4 oxidation state, and the dopant precursor comprises a dopant element in a +4 oxidation state.

In some embodiments, the dopant precursor comprises a compound that can be represented by the formula M(RCp)ₓ(L)_{y} wherein M is a rare earth metal, wherein R is selected from H, Me, Et, iPr, and tBu, and wherein L is selected from N,N′-diisopropylacetamidinate, N,N′-di-tert-butylacetamidinate, N,N′-diisopropylformamidinate, and N,N′-di-tert-butylformamidinate.

In some embodiments, a process of forming doped hafnium zirconium oxide as described herein comprises pulsing two different dopant precursors, in particular a first dopant precursor and a second dopant precursor. In some embodiments, the first dopant precursor and the second dopant are independently selected from a compound that can be represented by the formula M(RCp)ₓ(L)_{y} wherein M is a rare earth metal, wherein R is selected from H, Me, Et, iPr, and tBu, and wherein L is selected from N,N′-diisopropylacetamidinate, N,N′-di-tert-butylacetamidinate, N,N′-diisopropylformamidinate, and N,N′-di-tert-butylformamidinate.

Suitable rare earth metals include lanthanum, cerium, praseodymium, neodymium, promethium, samarium, europium, gadolinium, terbium, dysprosium, holmium, erbium, thulium, ytterbium, and lutetium.

In some embodiments, the lanthanum precursor comprises Lanthanum in a +4 oxidation state.

In some embodiments, the lanthanum precursor comprises one or more ligands selected from the list consisting of alkylamido ligands, alkoxy ligands, cyclopentadienyl ligands, alkylcyclopetadienyl ligands, beta-diketonate ligands, alkyl ligands, amidinate ligands, and halide ligands.

In some embodiments, the lanthanum precursor comprises a compound that can be represented by the formula La(RCp)₂(L) wherein R is selected from H, Me, Et, iPr, and tBu, and wherein L is selected from N,N′-diisopropylacetamidinate, N,N′-di-tert-butylacetamidinate, N,N′-diisopropylformamidinate, and N,N′-di-tert-butylformamidinate.

In some embodiments, the ruthenium precursor comprises Ruthenium in an oxidation state of +2 or lower, for example in an oxidation state of +2, +1, or 0. Such relatively low Ru oxidation states correlate with ALD deposition processes comprising the use of a ruthenium precursor having relatively faster nucleation and a lower ALD window temperature, without significantly affecting growth per cycle. In addition, when a ruthenium precursor is used for forming a conductive metal oxide electrode, e.g. a top electrode or a bottom electrode, ruthenium precursor oxidation state only weakly correlates with resistivity. Thus, an ALD process using a ruthenium precursors comprising ruthenium in a low oxidation state, e.g. an oxidation state of 0, and an oxygen reactant such as O₂, can advantageously offer a low deposition temperature, low resistivity, and fast nucleation.

In some embodiments the ruthenium precursor can comprise ruthenium in a +3 or +4 oxidation state.

In some embodiments, the ruthenium precursor comprises ruthenium in a +8 oxidation state. Examples of such precursors include RuO₄.

In some embodiments, the ruthenium precursor comprises one or more alkyl-substituted benzene ligands and one or more diene ligands. Examples of such precursors include Ru(ethylbenzene)(1,3-butadiene).

In some embodiments, the ruthenium precursor comprises one or more alkyl-substituted diene ligands and one or more carbonyl ligands. Examples of such precursors include Ru(2,3-dimethyl-1,3-butadiene)(CO)₃.

In some embodiments, the ruthenium precursor comprises a cyclohexadiene ligand such as a 1,3-cyclohexadiene or 1,4-cyclohexadiene ligand. Examples of such precursors include (isopropylmethylbenzene)(cyclohexadiene)ruthenium.

In some embodiments, the ruthenium precursor comprises a butadiene ligand such as a 1,3-butadiene ligand. Examples of such precursors include (ethylbenzene)(1,3-butadiene)ruthenium.

In some embodiments, the ruthenium precursor comprises one or more chelating or non-chelating alkoxy ligands.

In some embodiments, the ruthenium precursor can comprise a chelating ligand. For example, the ruthenium precursor can comprise a beta-diketonate ligand. For example, the ruthenium precursor can comprise tris(2,2,6,6-tetramethyl-3,5-heptanedionato) ruthenium(III).

In some embodiments, the ruthenium precursor comprises a ruthenium π complex. In some embodiments, the ruthenium precursor can comprise one or more substituted or unsubstituted cyclopentadienyl ligands. For example, the ruthenium precursor can comprise at least one of bis(η⁵-ethylcyclopentadienyl)ruthenium(II), (η⁶-isopropylmethylbenzene)(η⁵-cycloheptadienyl)ruthenium, (η⁶-ethylbenzene)(η⁵-cycloheptadienyl)ruthenium, (η⁶-ethylbenzene)(η⁵-ethylcycloheptadienyl)ruthenium, and bis(η⁵-cyclopentadienyl)ruthenium(II).

In some embodiments, the ruthenium precursor comprises one or more heterocyclic ligands, such as heterocyclic aromatic ligands. In some embodiments, the ruthenium precursor can comprise at least one substituted or unsubstituted pyridine ligand. In some embodiments, a pyridine ligand can comprise one or more alkyl substituents. Suitable alkyl substituents can include methyl, ethyl, propyl, and butyl substituents. For example, the ruthenium precursor can comprise at least one of (η⁵-ethylcyclopentadienyl)(pyridine)ruthenium(II) and bis(dimethylpyridine)ruthenium(II).

In some embodiments, the ruthenium precursor comprises one or more linear, branched, or cyclic dienyl ligands. For example, the ruthenium precursor can comprise at least one of bis(η⁵-2,4-dimethylpentadienyl)ruthenium(II) and an anionic dienyl ligand such as Ru(η⁵-cycloheptadienyl)₂. In some embodiments, the ruthenium precursor comprises at least one of a butadiene derived ligand and a cyclohexadiene derived ligand.

In some embodiments, the ruthenium precursor comprises one or more carbonyl ligands. For example, the ruthenium precursor can comprise one or more carbonyl ligands and one or more cyclopentadienyl ligands. For example, the ruthenium precursor can comprise one or more carbonyl ligands, one or more cyclopentadienyl ligands, and one or more alkyl ligands. For example, the ruthenium precursor can comprise (cyclopentadienyl)bis(carbonyl)ethyl ruthenium(II).

In some embodiments, the cerium precursor comprises Cerium in a +4 oxidation state.

In some embodiments, the cerium precursor comprises cerium in a +3 oxidation state.

In some embodiments, the cerium precursor comprises one or more ligands selected from alkylamido ligands, dialkylamido ligands, cyclopentadienyl ligands, alkylcyclopentadienyl ligands, amidinate ligands, beta-diketonate ligands, and alkoxide ligands.

In some embodiments, the cerium precursor comprises a compound that can be represented by the formula Ce(RCp)₂(L) wherein R is selected from H, Me, Et, iPr, and tBu, and wherein L is selected from N,N′-diisopropylacetamidinate, N,N′-di-tert-butylacetamidinate, N,N′-diisopropylformamidinate, and N,N′-di-tert-butylformamidinate.

In some embodiments, the scandium precursor comprises Scandium in a +4 oxidation state.

In some embodiments, the scandium precursor comprises scandium in a +3 oxidation state.

In some embodiments, the scandium precursor comprises one or more ligands selected from alkylamido ligands, dialkylamido ligands, cyclopentadienyl ligands, alkylcyclopentadienyl ligands, amidinate ligands, beta-dikeontate ligands, and alkoxide ligands.

In some embodiments, the scandium precursor comprises a cyclopentadienyl ligand such as tris(cyclopentadienyl)scandium.

In some embodiments, the scandium precursor comprises a cationic scandium amide complex. An example of such a precursor is Sc[N(SiHMe₂)₂]₃(THF), with Me standing for methyl and THF standing for tetrahydrofuran.

In some embodiments, the scandium precursor comprises an amidinate and an unsubstituted or alkyl-substituted cyclopentadienyl ligand. Examples such precursors include Sc(Cp)₂(N^{iPr} Me-amd), Sc(EtCp)₂(N^{iPr} Me-amd), and Sc(iPrCp)₂(N^{iPr} Me-amd). It shall be understood that Cp stands for cyclopentadienyl, iPr stands for isopropyl, Me stands for methyl, amd stands for amidinate, N^{iPr} indicates a nitrogen-bound isopropyl group. This precursor nomenclature is explained, and methods for producing such precursors are disclosed, in the United States patent application having publication no. US 2016/0315168 Al.

In some embodiments, the scandium precursor comprises a compound that can be represented by the formula Sc(RCp)₂(L) wherein R is selected from H, Me, Et, iPr, and tBu, and wherein L is selected from N,N′-diisopropylacetamidinate, N,N′-di-tert-butylacetamidinate, N,N′-diisopropylformamidinate, and N,N′-di-tert-butylformamidinate.

In some embodiments, the oxygen reactant comprises one or more of H₂O, H₂O₂, O₂, O₃, N₂O, NO, and NO₂.

Further described herein is a system that comprises one or more processing chambers. The system further comprises a hafnium precursor source. The hafnium precursor source comprises a hafnium precursor. The system further comprises a zirconium precursor source. The zirconium precursor source comprises a zirconium precursor. The system further comprises a dopant precursor source. The dopant precursor source comprises a dopant precursor. The system further comprises an oxygen reactant source. The oxygen reactant source comprises an oxygen reactant. The system further comprises a controller. The controller is configured to control gas flow into the one or more processing chambers and to process a substrate by means of a method as described herein.

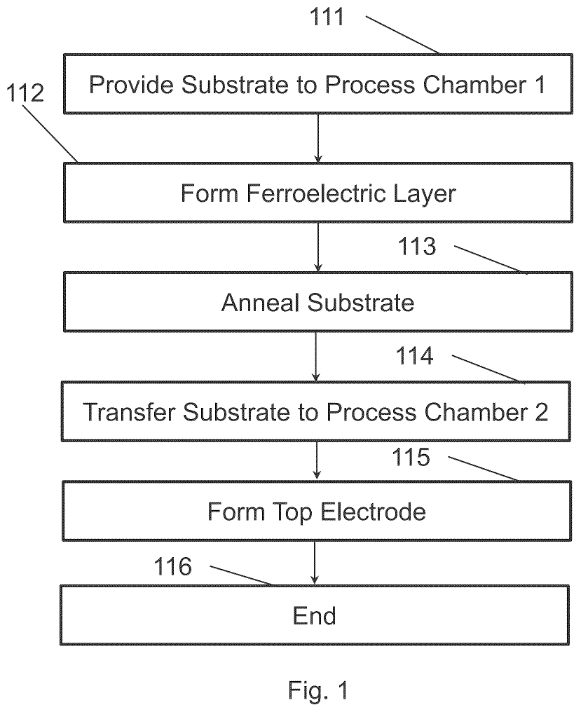

In an exemplary embodiment, reference is made to FIG. 1. FIG. 1 shows an embodiment of a method as described. The method comprises a step (111) of providing a substrate to a first processing chamber. Then, the method comprises a step (112) of forming a ferroelectric layer on the substrate. The ferroelectric layer can comprise doped or undoped HfZrO₂. Alternatively, the ferroelectric layer can comprise doped HfO₂. Suitably, the ferroelectric layer can be formed by means of a cyclical deposition process such as atomic layer deposition. In some embodiments, the ferroelectric layer is formed by means of a method as described herein. In a further step (113), the substrate is subjected to an annealing step. For example, the substrate can be annealed in a substantially inert annealing ambient comprising a noble gas. Other suitable annealing ambients include oxygen-containing ambients such as O₂-containing ambients. Suitably, the anneal can be carried out at an annealing temperature of at least 300° C. to at most 500° C., or of at least 350° C. to at most 450° C., for example at a temperature of around 400° C. After the anneal, the substrate can be transferred (114) to a second process chamber. The second process chamber can be a dedicated process chamber, or another chamber such as a load lock. Suitably, the first process chamber and the second process chamber can be comprised in the same vacuum system such that processes can be carried out on substrates in the first process chamber and the second process chamber without any intervening vacuum break, i.e. processes can be processed in the first process chamber and in the second process chamber without exposure of the substrate to atmospheric air in between the processes in the first process chamber and the second process chamber. In the second process chamber, a top electrode can be formed on the ferroelectric layer in a further step (115). Suitable top electrodes can be formed using an atomic layer deposition process and include semiconducting oxides such as indium-gallium-zinc-oxide (IGZO), indium-tin-oxide (ITO), nickel oxide (NiO), and cuprous oxide (Cu₂O). Thus, the ferroelectric layer can be given a heat treatment to improve its properties without subjecting the top electrode to a heat treatment which might harm its properties. After the step (115) of forming the top electrode, the method ends (116), and the substrate can be subjected to further processing steps, if desired.

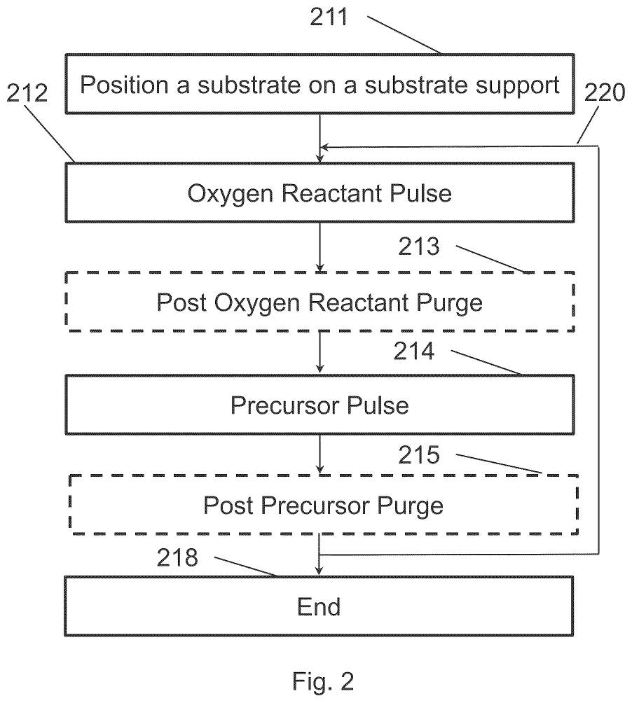

FIG. 2 schematically shows a process flow of an embodiment of a method as described herein. The method comprises a step (211) of positioning a substrate on a substrate support. Then, the method comprises executing (212) an oxygen reactant pulse. The oxygen reactant pulse comprises exposing the substrate to an oxygen reactant. Any suitable oxygen reactant as described herein can be used during the oxygen reactant pulse. Suitable oxygen reactants include oxygen-containing reactants such as O₂ and O₃, oxygen and hydrogen containing reactants such as H₂O and H₂O₂, and oxygen and nitrogen containing reactants such as N₂O, and NO, and NO₂. Optionally, a post oxygen reactant purge (213) is then carried out. The post oxygen reactant purge (213) comprises exposing the substrate to an oxygen reactant. Then, the method comprises executing (214) a precursor pulse. The precursor pulse comprises a step of exposing the substrate to a precursor. Suitable precursors include hafnium precursors or zirconium precursors as described herein. After the precursor pulse (214), the method optionally comprises executing (215) a post precursor purge. The oxygen reactant pulse (212), the precursor pulse (214), and their respective optional purges (213, 215) are repeated (220) one or more times until a material having a desired thickness has been deposited. After a material having a desired thickness has been deposited, the method ends (218).

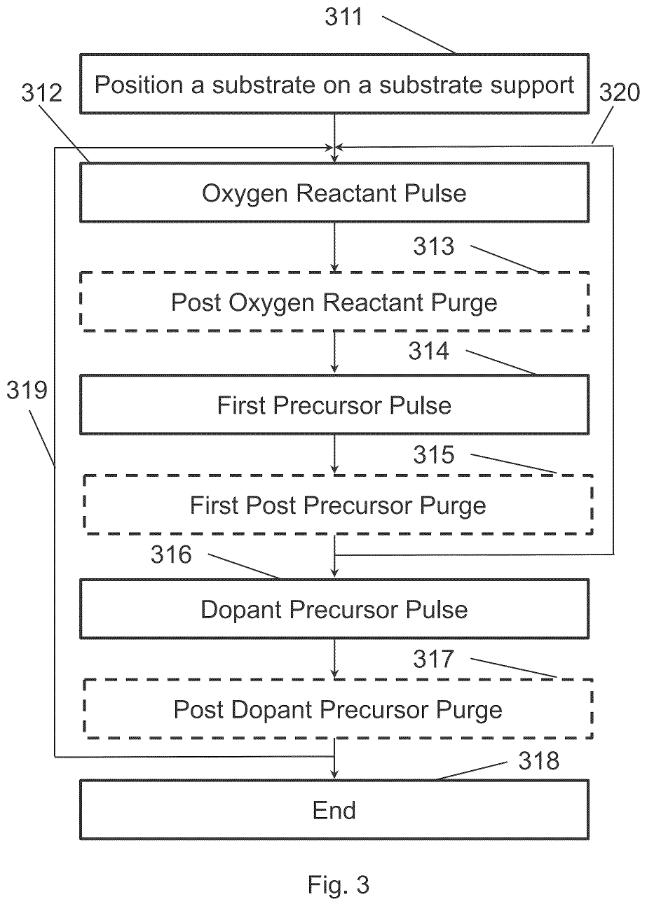

FIG. 3 schematically shows a process flow according to another embodiment of a method as described herein. The method comprises a step (311) of positioning a substrate on a substrate support. Then, the method comprises executing (312) an oxygen reactant pulse. The oxygen reactant pulse comprises exposing the substrate to an oxygen reactant. Any suitable oxygen reactant as described herein can be used during the oxygen reactant pulse. Optionally, a post oxygen reactant purge (313) is then carried out. The post oxygen reactant purge (313) comprises exposing the substrate to an oxygen reactant. Then, the method comprises executing (314) a first precursor pulse. The first precursor pulse comprises a step of exposing the substrate to a first precursor. Suitable first precursors include hafnium precursors or zirconium precursors as described herein. After the first precursor pulse (314), the method optionally comprises executing (315) a first post precursor purge. The oxygen reactant pulse (312), the first precursor pulse (314), and their respective optional purges (313, 315) are repeated (320) one or more times, to form one or more first precursor cycles (320). Then, a dopant precursor pulse (316) is carried out. The dopant precursor pulse (316) comprises exposing the substrate to a dopant precursor. Suitable dopant precursors are disclosed elsewhere herein. After the dopant precursor pulse (316), a post dopant precursor purge (317) is carried out. The post dopant precursor purge comprises exposing the substrate to a purge gas. The first precursor cycles (320), the dopant precursor pulse (316), and any corresponding purges, are repeated (319) one or more times to form one or more super cycles (319). After a suitable amount of super cycles (319) have been carried out, the method ends.

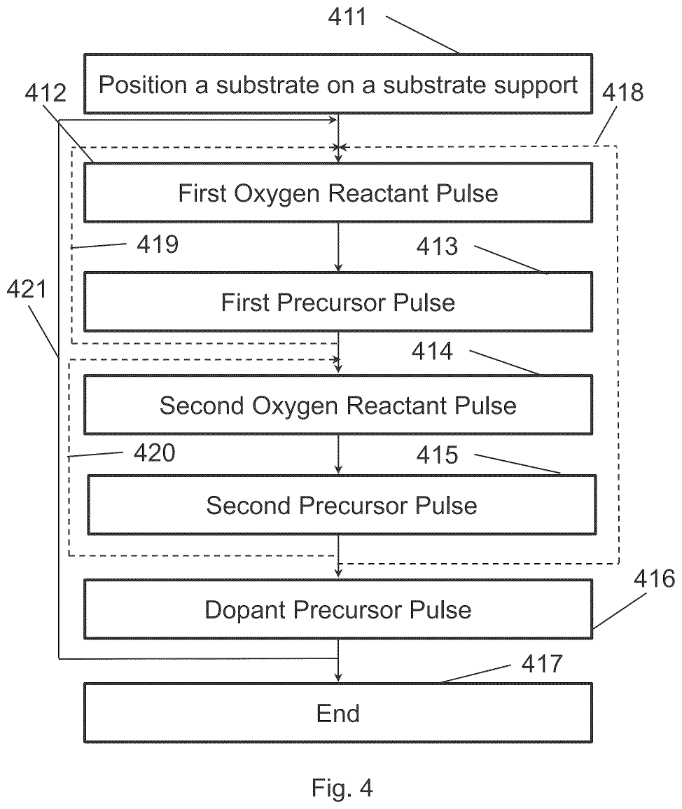

FIG. 4 schematically shows a process flow according to another embodiment of a method as described herein. The method comprises a step (411) of positioning a substrate on a substrate support. Then, the method comprises executing (412) a first oxygen reactant pulse. The first oxygen reactant pulse comprises exposing the substrate to a first oxygen reactant. Any suitable oxygen reactant as described herein can be used during the first oxygen reactant pulse. Then, the method comprises executing (413) a first precursor pulse. The first precursor pulse comprises a step of exposing the substrate to a first precursor. Suitable first precursors include hafnium precursors or zirconium precursors as described herein. The oxygen reactant pulse (412) and the first precursor pulse (413) form a first sub cycle (419) which can optionally be repeated (419) one or more times.

Then, the method of FIG. 4 comprises executing (414) a second oxygen reactant pulse. The second oxygen reactant pulse (414) comprises exposing the substrate to a second oxygen reactant. Any suitable oxygen reactant as described herein can be used during the second oxygen reactant pulse. Then, the method comprises executing (415) a second precursor pulse. The second precursor pulse (415) comprises a step of exposing the substrate to a second precursor. Suitable second precursors include hafnium precursors or zirconium precursors as described herein. It shall be understood that the first precursor and the second precursor are different. The first oxygen reactant and the second oxygen reactant can be the same or they can be different. The second oxygen reactant pulse (414) and the second precursor pulse (415) form a second sub cycle (420) which can optionally be repeated (420) one or more times.

The one or more first sub cycles (419) and the one or more second sub cycles (420) together form a deposition cycle (418). The deposition cycle (418) can optionally be repeated one or more times. Then, a dopant precursor pulse (416) is carried out. The dopant precursor pulse (416) comprises exposing the substrate to a dopant precursor. Suitable dopant precursors are disclosed elsewhere herein. Note that optionally, a purge can be executed after one or more of the pulses executed in an embodiment of the presently described method of FIG. 4.

The one or more deposition cycles (418) and the subsequent dopant precursor pulse (416) together form a super cycle (421). Optionally, the super cycle (421) is repeated one or more times. After a suitable amount of super cycles (421) have been carried out, the method ends (417).

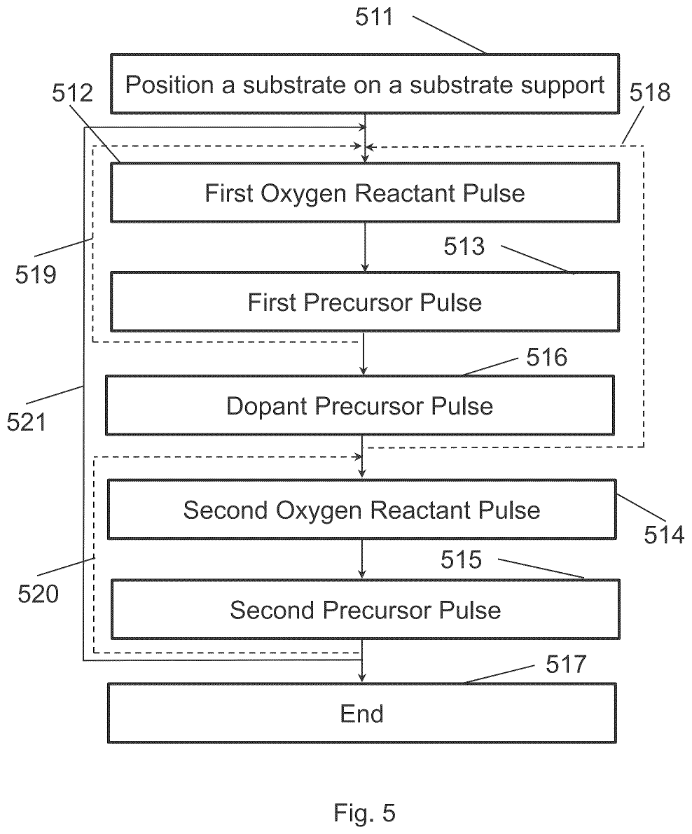

FIG. 5 schematically shows a process flow according to another embodiment of a method as described herein. The method comprises a step (511) of positioning a substrate on a substrate support. Then, the method comprises executing (512) a first oxygen reactant pulse. The first oxygen reactant pulse comprises exposing the substrate to a first oxygen reactant. Any suitable oxygen reactant as described herein can be used during the first oxygen reactant pulse. Then, the method comprises executing (513) a first precursor pulse. The first precursor pulse comprises a step of exposing the substrate to a first precursor. Suitable first precursors include hafnium precursors or zirconium precursors as described herein. The first oxygen reactant pulse (512) and the first precursor pulse (513) form a first sub cycle (519) which can optionally be repeated (519) one or more times.

The one or more first sub cycles (519) are followed by a dopant precursor pulse (516). The dopant precursor pulse (516) comprises exposing the substrate to a dopant precursor. Suitable dopant precursors are disclosed elsewhere herein. The one or more first sub cycles (519) and the dopant precursor pulse (516) together form a first cycle (518) which can optionally be repeated (518) one or more times.

Then, the method of FIG. 5 comprises executing (514) a second oxygen reactant pulse. The second oxygen reactant pulse (514) comprises exposing the substrate to a second oxygen reactant. Any suitable oxygen reactant as described herein can be used during the second oxygen reactant pulse. Then, the method comprises executing (515) a second precursor pulse. The second precursor pulse (515) comprises a step of exposing the substrate to a second precursor. Suitable second precursors include hafnium precursors or zirconium precursors as described herein. It shall be understood that the first precursor and the second precursor are different. The first oxygen reactant and the second oxygen reactant can be the same or they can be different. The second oxygen reactant pulse (514) and the second precursor pulse (515) form a second sub cycle (520) which can optionally be repeated (520) one or more times. Note that optionally, a purge can be executed after one or more of the pulses executed in an embodiment of the presently described method of FIG. 5.

The one or more first cycles (518) and the subsequent one or more second sub cycles (520) together form a super cycle (521). Optionally, the super cycle (521) is repeated one or more times. After a suitable amount of super cycles (521) have been carried out, the method ends (517).

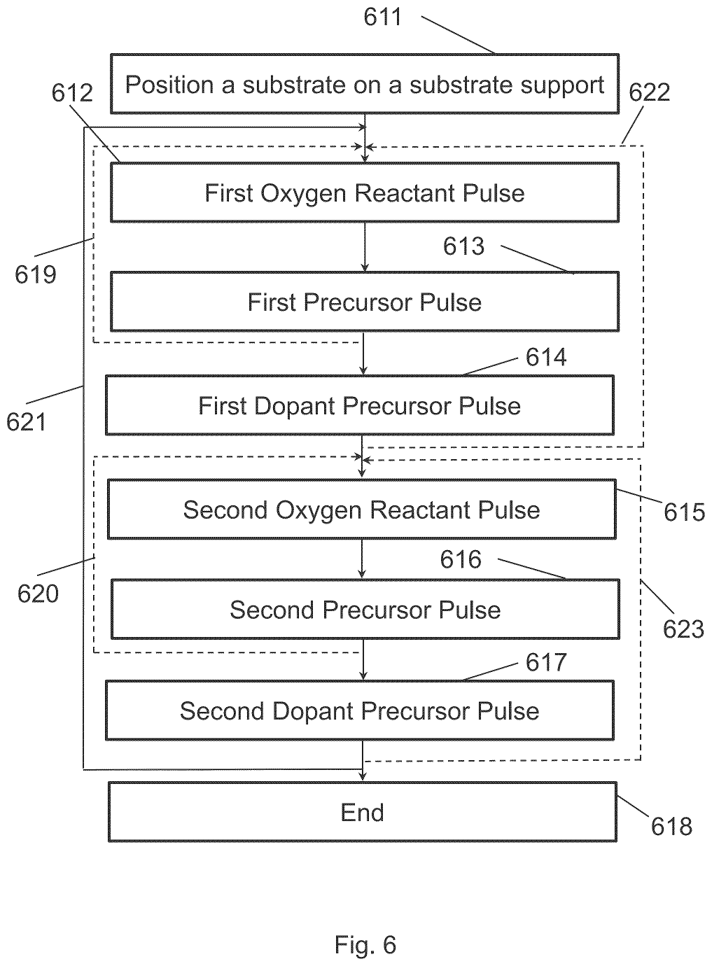

FIG. 6 schematically shows a process flow according to another embodiment of a method as described herein. The method comprises a step (611) of positioning a substrate on a substrate support. Then, the method comprises executing (612) a first oxygen reactant pulse. The first oxygen reactant pulse comprises exposing the substrate to a first oxygen reactant. Any suitable oxygen reactant as described herein can be used during the first oxygen reactant pulse. Then, the method comprises executing (613) a first precursor pulse. The first precursor pulse comprises a step of exposing the substrate to a first precursor. Suitable first precursors include hafnium precursors or zirconium precursors as described herein. The first oxygen reactant pulse (612) and the first precursor pulse (613) form a first sub cycle (619) which can optionally be repeated (619) one or more times.

The one or more first sub cycles (619) are followed by a first dopant precursor pulse (614). The first dopant precursor pulse (614) comprises exposing the substrate to a dopant precursor. Suitable dopant precursors are disclosed elsewhere herein. The one or more first sub cycles (619) and the dopant precursor pulse (614) together form a first cycle (622) which can optionally be repeated (622) one or more times.

Then, the method of FIG. 6 comprises executing (615) a second oxygen reactant pulse. The second oxygen reactant pulse (615) comprises exposing the substrate to a second oxygen reactant. Any suitable oxygen reactant as described herein can be used during the second oxygen reactant pulse. Then, the method comprises executing (616) a second precursor pulse. The second precursor pulse (616) comprises a step of exposing the substrate to a second precursor. Suitable second precursors include hafnium precursors or zirconium precursors as described herein. The second oxygen reactant pulse (615) and the second precursor pulse (616) form a second sub cycle (620) which can optionally be repeated (620) one or more times. After the one or more second sub cycles (620), a second dopant precursor pulse (617) is carried out. The second dopant precursor pulse (617) comprises exposing the substrate to a dopant precursor. Suitable dopant precursors are disclosed elsewhere herein. The one or more second sub cycles (620) and the second dopant precursor pulse (617) together form a second cycle (623) which can optionally be repeated (623) one or more times. Note that optionally, a purge can be executed after one or more of the pulses executed in an embodiment of the presently described method of FIG. 6. It shall be understood that the first precursor and the second precursor are different. The first oxygen reactant and the second oxygen reactant can be the same or they can be different. The first dopant precursor and the second dopant precursor can be the same or they can be different. In some embodiments, the first dopant precursor comprises a first dopant which is identical to a second dopant comprised in the second dopant precursor. In some embodiments, the first dopant precursor comprises a first dopant which different from a second dopant comprised in the second dopant precursor.

The one or more first cycles (622) and the subsequent one or more second cycles (623) together form a super cycle (621). The super cycle (621) is repeated one or more times. After a suitable amount of super cycles (621) have been carried out, the method of FIG. 6 ends (617).

A method according to FIG. 6 can include heating the substrate to a desired deposition temperature within the reaction chamber. In some embodiments, a method according to FIG. 6 includes heating the substrate to a temperature of less than 800° C. For example, in some embodiments of the disclosure, heating the substrate to a deposition temperature may comprise heating the substrate to a temperature between approximately 20° C. and approximately 800° C., about 100° C. and about 500° C., about 150° C. and about 450° C., or about 200° C. and about 400° C., or about 200° C. and about 250° C., or about 250° C. and about 300° C., or about 300° C. and about 350° C., or about 350° C. and about 400° C.

In addition to controlling the temperature of the substrate, a pressure within the reaction chamber may also be regulated. For example, in some embodiments of the disclosure, the pressure within the reaction chamber during a method according to FIG. 2 may be less than 760 Torr or between 0.2 Torr and 760 Torr, about 1 Torr and 100 Torr, or about 1 Torr and 10 Torr, or about 0.5 Torr and 10 Torr, or less than 3 Torr, or less than 2 Torr, or less than 1 Torr.

In some embodiments, a method according to FIG. 6 can be carried out at a pressure of at least 1 Torr to at most 5 Torr, and at a temperature of at least 175° C. to at most 300° C. Suitable first precursor include Hafnium precursors such as homoleptic hafnium precursors such as homoleptic hafnium precursors comprising alkylamido ligands, such as Tetrakis(ethylmethylamido)hafnium(IV). Suitable second precursors include Zirconium precursors such as homoleptic zirconium precursors such as homoleptic zirconium precursors comprising alkylamido ligands, such as Tetrakis(ethylmethylamido)zirconium(IV). In some embodiments, zirconium precursor can be used as a first precursor and a hafnium precursor can be used as a second precursor, or vice versa. In some embodiments, the first oxygen reactant comprises ozone and the second oxygen reactant comprises water. In some embodiments, cycles in which ozone is used as an oxygen reactant can be carried out at a substrate temperature of at least 275° C. to at most 300° C. In some embodiments, cycles in which water is used as an oxygen reactant can be carried out at a temperature of at least 175° C. to at most 250° C.

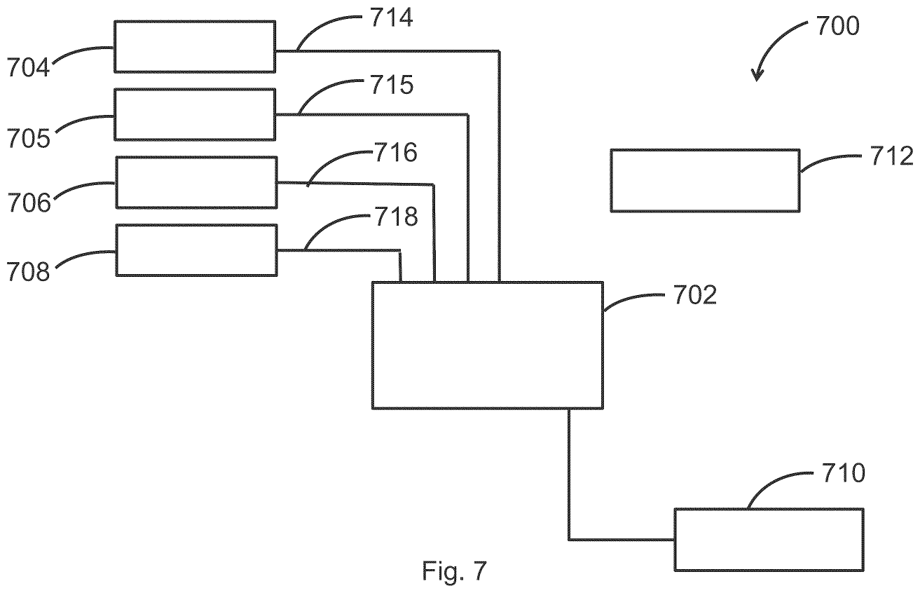

FIG. 7 illustrates a system (700) in accordance with exemplary embodiments of the disclosure. The system (700) can be configured to perform a method as described herein and/or form a structure or device portion as described herein. In the illustrated example, the system (700) includes one or more reaction chambers (702), a first precursor gas source (704), a dopant precursor gas source (706), an oxygen reactant gas source (708), an exhaust (710), and a controller (712). In some embodiments, the system further comprises at least one of a second precursor gas source (not shown) and a second dopant precursor gas source (not shown). The reaction chamber (702) can include an ALD reaction chamber.

The first precursor gas source (704) can include a vessel and one or more precursors as described herein-alone or mixed with one or more carrier (e.g., noble) gases. The dopant precursor gas source (706) can include a vessel and one or more dopant precursors as described herein-alone or mixed with one or more carrier gases. The oxygen reactant gas source (308) can include one or more oxygen reactants as described herein.

Although illustrated with four gas sources (704)-(708), the system (700) can include any suitable number of gas sources. The gas sources (704)-(708) can be coupled to the reaction chamber (702) via the lines (714)-(718), which can each include flow controllers, valves, heaters, and the like. The exhaust (710) can include one or more vacuum pumps.

The controller (712) includes electronic circuitry and software to selectively operate valves, manifolds, heaters, pumps and other components included in the system (700). Such circuitry and components operate to introduce precursors, reactants, and purge gases from the respective sources (704)-(708). The controller (712) can control timing of gas pulse sequences, temperature of the substrate and/or reaction chamber, pressure within the reaction chamber, and various other operations to provide proper operation of the system (700). The controller (712) can include control software to electrically or pneumatically control valves to control flow of precursors, reactants and purge gases into and out of the reaction chamber (702). The controller (712) can include modules such as a software or hardware component, e.g., a FPGA or ASIC, which performs certain tasks. A module can advantageously be configured to reside on the addressable storage medium of the control system and be configured to execute one or more processes as described herein.

Other configurations of the system (700) are possible, including different numbers and kinds of precursor and oxygen reactant sources and optionally further including purge gas sources. For example, the system (700) can further include a second dopant precursor source that comprises a second dopant precursor as described herein. Further, it will be appreciated that there are many arrangements of valves, conduits, precursor sources, and purge gas sources that may be used to accomplish the goal of selectively feeding gases into the reaction chamber (702). Further, as a schematic representation of a system, many components have been omitted for simplicity of illustration, and such components may include, for example, various valves, manifolds, purifiers, heaters, containers, vents, and/or bypasses.

During operation of the system (700), substrates, such as semiconductor wafers (not illustrated), are transferred from, e.g., a substrate handling system to the reaction chamber (702). Once the substrate(s) are transferred to the reaction chamber (702), one or more gases from the gas sources (704)-(708), such as precursors, reactants, carrier gases, and/or purge gases, are introduced into the reaction chamber (702).

In some embodiments, a system such as the system (700) of FIG. 7 can be constructed and arranged for forming bottom electrode, an intermediate layer, and a top electrode in the same reaction chamber. The intermediate layer can comprise one or more of a high-k layer, an antiferroelectric layer, and a ferroelectric layer. In some embodiments, a system such as the system (700) of FIG. 7 can be constructed and arranged for forming a ruthenium oxide bottom electrode, a hafnium zirconium oxide layer, and a ruthenium oxide top electrode in the same reaction chamber (702). Optionally, the hafnium zirconium oxide layer can be doped with ruthenium. Depositing these layers in the same reaction chamber (702) means that the interface between the layers, e.g. a RuO₂/HfZrO₂ interface, is pristine, without any airborne contaminants or unintended oxidation. Depositing a conductive electrode such as RuO₂ can also result in improvements in process throughput, reduce leakage and reduce crystallization temperature of an intermediate layer such as HfZrO₂.

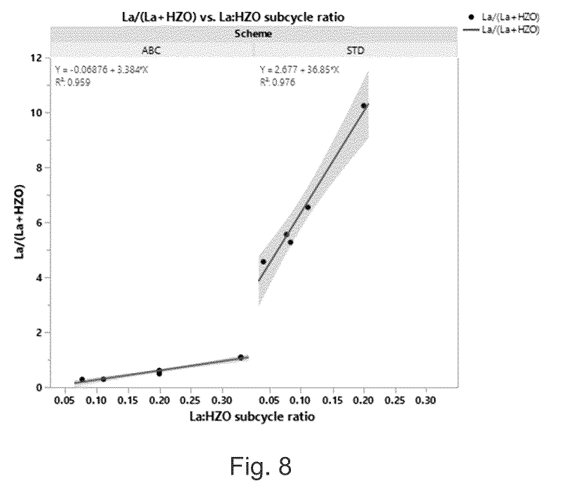

In a further example, reference is made to FIG. 8. FIG. 8 comprises two data sets: a left-hand data-set and a right-hand data set. The left-hand data set, denoted ABC, shows lanthanum concentration as a function of sub cycle ratio when a lanthanum pulse follows a precursor pulse. The right-hand data set, denoted STD, shows lanthanum concentration as a function of sub cycle ratio when a lanthanum pulse follows an oxygen reactant pulse. Note that the lanthanum concentration is shown on the vertical axis, and is expressed in atomic percent. Both STD and ABC films have a target thickness of around 10 nm. The ABC films had a slightly lower thickness, as measured with spectroscopic ellipsometry, which is consistent with lower La dopant incorporation (see below). Compositional analyses were performed using x-ray photoelectron spectroscopy.

In an ABC deposition process according to the present example, an ALD pulsing scheme according to the following formula was used: N[x(B+A1+B+A2)+C], in which N is the number of deposition cycles, x is the number of hafnium zirconium oxide sub-cycles, B denotes a pulse of H₂O, A1 denotes a pulse of a hafnium precursor, A2 denotes a pulse of a hafnium precursor, and C denotes a pulse of a lanthanum precursor. In an embodiment according to the present example, a hafnium zirconium oxide sub cycle refers to a sequence of a H₂O pulse, a hafnium precursor pulse, a H₂O pulse, and a zirconium precursor pulse; in the given order. Characteristic of such an ABC deposition process is that the lanthanum precursor pulse follows a hafnium precursor pulse. In an ABC deposition process, the sub cycle ratio is defined as being equal to 1/(1+x), in other words, the sub cycle ratio is the number of C pulses divided by the number of hafnium zirconium oxide sub cycles. The ABC deposition process advantageously allows incorporating minute amounts of lanthanum in a hafnium zirconium oxide film formed using ALD, even at high sub cycle ratios, which can provide excellent uniformity of lanthanum doping in resulting lanthanum-doped hafnium zirconium oxide films.

In a comparative STD deposition process, an ALD pulsing scheme according to the following formula was used: N[y(A1+B+A2+B)+C], in which N is the number of deposition cycles, y is the number of hafnium zirconium oxide cub-cycles, B denotes a pulse of H₂O, A1 denotes a pulse of a hafnium precursor, A2 denotes a pulse of a hafnium precursor, and C denotes a pulse of a lanthanum precursor. In an embodiment according to the present example, a hafnium zirconium oxide sub cycle refers to a sequence of a H₂O pulse, a hafnium precursor pulse, a H₂O pulse, and a zirconium precursor pulse; in the given order. Characteristic of such a STD deposition process is that the lanthanum precursor pulse follows a H₂O pulse. In an STD deposition process, analogous to the case of an STD deposition process, the sub cycle ratio is defined as being equal to 1/(1+y), in other words, the sub cycle ratio is the number of C pulses divided by the number of hafnium zirconium oxide sub cycles. The STD deposition process results in rapid increase of lanthanum concentration as a function of increasing sub cycle ratio. Thus, obtaining lightly lanthanum doped hafnium zirconium oxide films is difficult with a STD deposition process; when low sub cycle ratios are used, a hafnium zirconium oxide containing only little lanthanum can be obtained, but lanthanum does not tend to be uniformly distributed in such films.

In the STD and ABC processes of FIG. 7, the hafnium precursor was tetrakis(ethylmethylamino)hafnium, the zirconium precursor was tetrakis(ethylmethylamino)zirconium, and the lanthanum precursor was La(iPrCp)₂(iPr-amd), in which iPr stands for isopropyl, Cp stands for cyclopentadienyl, and amd stands for amidinate.

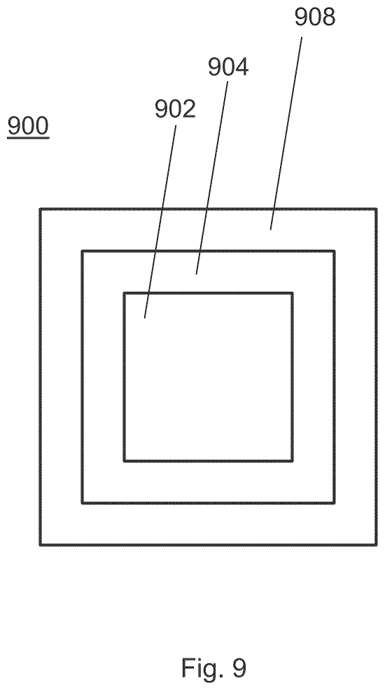

FIG. 9 illustrates a structure (900) in accordance with examples of the disclosure. This structure (900) is suitable for use in gate all around field effect transistors (GAA FET) (also referred to as lateral nanowire FET) devices and the like.

In the illustrated example, the structure (900) includes semiconductor material (902), dielectric material (904), an intermediate layer (906), and a conducting layer (908). The dielectric material (904) comprises a ferroelectric layer such as a hafnium oxide layer, or a hafnium zirconium oxide layer, or a doped hafnium zirconium oxide layer. In some embodiments, the intermediate layer (906) comprises a semiconducting oxide, such as a semiconducting oxide comprising a doping element which is also comprised in the ferroelectric layer.

In some embodiments, the ferroelectric layer has a thickness less than 20 nm, or from at least 1 nm to at most 15 nm, or from at least 2 nm to at most 10 nm, or from at least 2 nm to at most 5 nm, such as 4 nm.

The structure (900) can be formed overlying a substrate, including any substrate materials described herein. The intermediate layer (906) can be positioned between the conducting layer (908) and the dielectric material (906), as shown.

The semiconductor material (902) can include any suitable semiconducting material. For example, the semiconductor material (902) can include Group IV, Group III-V, or Group II-VI semiconductor material. By way of example, the semiconductor material (902) can include silicon.

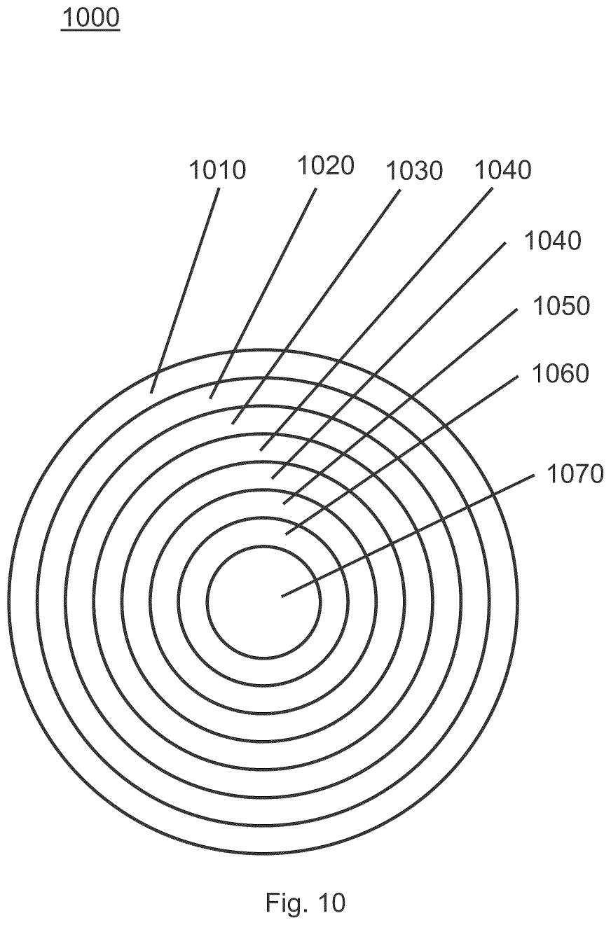

FIG. 10 illustrates an exemplary capacitor (1000). It includes a top electrode (1010,1070) which comprises two parts, i.e. an inner shell and an outer shell, in the embodiment shown. This notwithstanding, the top electrode may comprise just one part, or may comprise more than two parts, e.g. three or more parts. It shall be understood that the two parts of the top electrode (1010,1070) in the embodiment of FIG. 10 are electrically connected to each other (connection not shown), i.e. it shall be understood that during normal operation, they are kept at the same, or approximately the same, electrical potential. In some embodiments, the top electrode (1010,1070) comprises semiconducting oxide, such as a semiconducting oxide comprising a dopant element that is also comprised in a ferroelectric layer comprised in the Capacitor (1000).

The top electrode (1010,1070) may, for example, have a thickness of at least 0.5 nm to 5.0 nm, or of at least 1.0 nm to at most 4.0 nm, or of at least 2.0 nm to at most 3.0 nm, or of at least 0.5 nm to at most 2.5 nm, or of at least 0.6 nm to at most 2.0 nm, or of at least 0.7 nm to at most 1.5 nm. The capacitor (1000) further comprises a bottom electrode (1040). The bottom electrode (1040) comprises a layer deposited by means of a method as described herein. In some embodiments, the composition of the bottom electrode (1040) equals the composition of the top electrode (1010,1070). Alternatively, the composition of the bottom electrode (1040) may differ from the composition of the top electrode (1010,1070). The bottom electrode (1040) may, for example, have a thickness of at least 1.0 nm to at most 10.0 nm or of at least 3.0 nm to at most 7.0 nm, or of at least 0.5 nm to 5.0 nm, or of at least 1.0 nm to at most 4.0 nm, or of at least 2.0 nm to at most 3.0 nm, or of at least 0.5 nm to at most 2.5 nm, or of at least 0.6 nm to at most 2.0 nm, or of at least 0.7 nm to at most 1.5 nm.

The bottom electrode (1040) is separated from an outer shell of the top electrode (1010) by one or more dielectric layers (1020,1030). At least one of the one or more dielectric layers (1020,1030) comprises a ferroelectric layer that is formed by means of a method as described herein. The embodiment shown features two dielectric layers (1020,1030). The one or more dielectric layers (1020,1030) may comprise a high-k dielectric. In some embodiments, dielectric layer (1020) has the same composition as dielectric layer (1030). In some embodiments, dielectric layer (1020) has a different composition than dielectric layer (1030). The combined thickness of the two dielectric layers (1020,1030) may be, for example, from at least 0.5 nm to at most 10.0 nm or of at least 1.0 nm to at most 8.0 nm, or of at least 2.0 nm to at most 6.0 nm, or of at least 3.0 nm to at most 4.0 nm. An inner shell of the top electrode (1070) is separated from the bottom electrode (1040) by means of one or more dielectric layers (1050,1060). The embodiment shown features two such dielectric layers. At least one of the one or more dielectric layers (1050,1060) comprise a ferroelectric material formed in accordance with an embodiment of a method as described herein. In some embodiments, dielectric layer (1050) has the same composition as dielectric layer (1060). In some embodiments, dielectric layer (1050) has a different composition than dielectric layer (1060). The combined thickness of the dielectric layers (1050,1060) may be, for example, from at least 0.5 nm to at most 10.0 nm or of at least 1.0 nm to at most 8.0 nm, or of at least 2.0 nm to at most 6.0 nm, or of at least 3.0 nm to at most 4.0 nm. In some embodiments, the thickness of the one or more dielectric layers (1020,1030) between the outer shell of the top electrode (1010) and the bottom electrode (1040) equals the thickness of the one or more dielectric layers (1050,1060) between the inner shell of the top electrode (1070) and the bottom electrode (1040), e.g. within a margin of error of less than 2.0 nm, or less than 1.5 nm, or less than 1.0 nm, or less than 0.5 nm, or less than 0.4 nm, or less than 0.3 nm, or less than 0.2 nm, or less than 0.1 nm. A gap filling dielectric (1080) may be centrally disposed in the Capacitor (1080). Exemplary gap filling dielectrics include low-k dielectrics, e.g. SiOC, SiOCN, and the like.

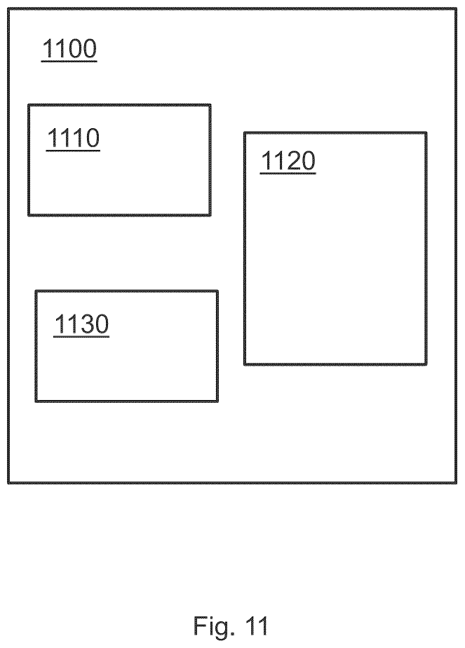

In a further example, reference is made to FIG. 11. FIG. 11 schematically shows a system (1100) comprising a first process chamber (1110), a second process chamber (1120), and a third process chamber (1130). The first process chamber (1110) can be arranged for forming a transparent semiconducting oxide layer on a substrate. In an exemplary embodiment, the transparent semiconducting oxide layer comprises RuO₂. The second process chamber (1120) can be arranged for forming a ferroelectric material on the substrate. Suitable ferroelectric materials include ruthenium-doped hafnium zirconium oxide. The third process chamber (1130) can comprise one or more heating elements such as heat exchangers and infrared lamps.

In some embodiments, a system according to FIG. 11 can be employed for forming a capacitor. The capacitor can comprise a ruthenium-doped hafnium zirconium oxide layer sandwiched between ruthenium oxide electrodes. For example, such a capacitor can be manufactured by first forming a ruthenium oxide bottom electrode in the first process chamber (1110). Then, a ruthenium-doped hafnium zirconium oxide layer can be formed in the second process chamber (1120) on the ruthenium oxide bottom electrode. Then, a ruthenium oxide top electrode can be formed in the first process chamber (1110) on the ruthenium-doped hafnium zirconium oxide layer. The substrate can be annealed in the third process chamber (1130) after one or more of forming the bottom electrode, forming the ruthenium-doped hafnium zirconium oxide layer, and after forming the top electrodes. Suitably, the aforementioned steps are sequentially executed in the same system (1100) without any intervening vacuum break. In some embodiments, the anneal is carried out at a temperature of less than 500° C., e.g. at a temperature of at least 100° C. to at most 450° C., or at a temperature of at least 200° C. to at most 400° C., such as at a temperature of 300° C.

In an exemplary embodiment, a system (1100) according to FIG. 11 can be employed for forming a structure comprising a substrate, a ferroelectric layer, and an electrode. In particular, a ferroelectric layer can be formed on the substrate in the second process chamber (1120). The ferroelectric layer can comprise, for example, one or more of doped-HfO₂, HfZrO₂, and doped HfZrO₂. Suitably, the ferroelectric layer can be formed using a cyclical deposition process such as atomic layer deposition. Then, the substrate comprising the ferroelectric layer can be annealed in the third process chamber (1130). The anneal can be performed, for example, at a temperature of 400° C. The anneal can be performed in inert atmosphere or in an oxidizing atmosphere. Suitable inert atmospheres include noble gasses such as Ar and He. Suitable oxidizing atmospheres include gasses or gas mixtures comprising an oxygen-containing gas such as O₂. After the anneal, an electrode can be formed on the ferroelectric layer in the third process chamber (1130). Suitably, the electrode can be formed using a cyclical deposition process such as atomic layer deposition. Suitable semiconducting oxides include indium gallium zinc oxide, indium tin oxide, nickel oxide, and cuprous oxide. Thus, the ferroelectric layer can be made to crystallize in a desirable phase, and the electrode is not exposed to high temperature or harsh environments during processing which can improve its properties.

In some embodiments, the third process chamber (1130) can function as a load lock. For example, the third process chamber (1130) can comprise a robot arm. Thus, throughput can be enhanced while minimizing the system's footprint.

In an exemplary embodiment, ruthenium (Ru) deposited by physical vapor deposition was oxidized by O₃ and formed a bottom electrode comprising elemental ruthenium and a thin layer of RuO₂ upon which a ferroelectric layer substantially consisting of hafnium zirconium oxide was deposited by means of atomic layer deposition (ALD). Ozone (O₃) oxidation can occur at any suitable temperature, such as at a temperature of 275° C. Titanium nitride was then sputtered as the top electrode to form a metal-insulator-metal (MIM) structure. As an alternative to sputtering, titanium nitride formed using a cyclical deposition method can be used as well. Upon capacitance-voltage (CV) and current-voltage (IV) measurements, the resulting 5 nm HfZrO₂ demonstrated a high dielectric constant >40 and an extremely low leakage in particular at the high field regime. Upon further analysis, it was identified that the reduction of the leakage at the high field regime is due to the mitigation of oxygen vacancy formation (which can be predominant when titanium nitride electrodes are used). The high dielectric constant is primarily due to successful crystallization of the layers at relatively low temperature (e.g. 420° C.). Further tests were done to confirm the formation of RuO₂ upon O₃ exposure. Finally, 4 nm HfZrO₂ was deposited on oxidized Ru electrodes to evaluate the crystallization of the layers, and upon a 400° C. anneal the mixed HfZrO₂ containing hafnium and zirconium in a 1:2 molar ratio was found to show excellent crystallization.

In a further exemplary embodiment, a RuO₂ lower electrode is deposited using atomic layer deposition. Then, the RuO₂ lower electrode is annealed in an inert or substantially inert gas such as a noble gas such as argon. Then, an insulating layer, e.g. dielectric, ferroelectric, or antiferroelectric, can be formed on the lower electrode. Suitable insulating layers include doped or undoped hafnium zirconium oxide. Then, a top electrode can be formed on the insulating layer. Suitable top electrodes include transition metal nitrides such as titanium nitride. In some embodiments, the top electrode comprises ruthenium oxide. Then, the resulting structure can be annealed, e.g. at a temperature of 400-500° C., such as at 420° C. for a duration of 30 minutes to 2 hours, e.g. for 1 hour. Suitable annealing ambients include nitrogen-containing gas mixtures such as substantially pure N₂.

1. A method of processing a substrate, the method comprising:
providing the substrate to a processing chamber; and
executing a plurality of deposition cycles, wherein a deposition cycle comprises a hafnium precursor pulse, a zirconium precursor pulse, an oxygen reactant pulse, and a first dopant pulse,
wherein the hafnium precursor pulse comprises exposing the substrate to a hafnium precursor;
wherein the zirconium precursor pulse comprises exposing the substrate to a zirconium precursor;
wherein the oxygen reactant pulse comprises exposing the substrate to an oxygen reactant;
wherein the first dopant pulse comprises exposing the substrate to a first dopant precursor, the first dopant precursor comprising a first dopant element;
thereby forming a doped hafnium zirconium oxide layer on the substrate; and
wherein the first dopant precursor pulse is carried out after one of the hafnium precursor pulse and the zirconium precursor pulse without any intervening oxygen reactant pulse.

2. The method according to claim 1, further wherein the deposition cycle further comprises a second dopant pulse that comprises exposing the substrate to a second dopant precursor, the second dopant precursor comprising a second dopant element, the second dopant element being different from the first dopant element.

3. The method according to claim 2, wherein at least one of the first dopant element and the second dopant element comprises cerium.

4. The method according to claim 1, wherein the first dopant element comprises lanthanum.

5. The method according to claim 1, wherein the first dopant element is selected from a list consisting of tin, tellurium, cerium, and lead.

6. The method according to claim 1, wherein the first dopant element is selected from a list consisting of ruthenium, palladium, rhenium, osmium, iridium, and platinum.

7. The method according to claim 1, wherein the first dopant element is molybdenum or tungsten.

8. The method according to claim 2, wherein the second dopant element is independently from the first dopant element selected from a list consisting of cerium, lanthanum, tin, tellurium, lead, ruthenium, palladium, rhenium, osmium, iridium, platinum, molybdenum, and tungsten.

9. The method according to claim 2, wherein at least one of the first dopant precursor and the second dopant precursor are independently selected from a compound that can be represented by the formula M(RCp)x(L)y, wherein M is a rare earth metal, wherein R is selected from H, Me, Et, iPr, and tBu, and wherein L is selected from N,N′-diisopropylacetamidinate, N,N′-di-tert-butylacetamidinate, N,N′-diisopropylformamidinate, and N,N′-di-tert-butylformamidinate.

10. The method according to claim 1, wherein the substrate comprises a surface layer, wherein the doped hafnium zirconium oxide layer is formed on the surface layer, wherein the surface layer comprises a surface layer conductive oxide, wherein the surface layer conductive oxide comprises the first dopant element and oxygen.

11. The method according to claim 1, wherein executing the plurality of deposition cycles is preceded by a step of forming a surface layer, the surface layer comprising a surface layer conductive oxide, wherein the surface layer conductive oxide comprises the first dopant element and oxygen.

12. The method according to claim 11, further comprising a step of forming a top electrode on the doped hafnium zirconium oxide layer, the top electrode comprising a top conductive oxide, the top conductive oxide comprising the first dopant element.

13. The method according to claim 12, wherein the surface layer and the top conductive oxide have a substantially identical composition.

14. The method according to claim 12, wherein at least one of the surface layer conductive oxide and the top conductive oxide comprise ruthenium oxide, and wherein the first dopant element comprises ruthenium.

15. The method according to claim 12, wherein the step of forming a top electrode on the doped hafnium zirconium oxide layer is preceded by annealing the doped hafnium zirconium oxide layer.

16. The method according to claim 15 being carried out in a system comprising a processing chamber, wherein the step of executing a plurality of deposition cycles and the step of annealing the doped hafnium zirconium oxide layer are carried out in first processing chamber.

17. The method according to claim 15 being carried in a system comprising a first processing chamber and a second processing chamber, wherein the step of executing a plurality of deposition cycles and the step of annealing the doped hafnium zirconium oxide layer are carried out in the first processing chamber, and wherein the step of forming the top electrode is carried out in the second processing chamber.

18. The method according to claim 16 being carried out in a system comprising a first processing chamber, a second processing chamber, and a third processing chamber, wherein the step of executing a plurality of deposition cycles is carried out in the first processing chamber, wherein the step of annealing the doped hafnium zirconium oxide layer is carried out in the second processing chamber, and wherein the step of forming the top electrode is carried out in the third processing chamber.

19. A system comprising:
one or more processing chambers;
a hafnium precursor source comprising a hafnium precursor;
a zirconium precursor source comprising a zirconium precursor;
a first dopant precursor source comprising a first dopant precursor;
a second dopant precursor source comprising a second dopant precursor;
an oxygen reactant source comprising an oxygen reactant; and
a controller, wherein the controller is configured to control gas flow into the one or more processing chambers and to process a substrate by the method according to claim 1.

20. A method of filling a precursor source that is operationally connectable to the system according to claim 19, the method comprising:
providing the precursor source; and
filling the precursor source with a precursor selected from a hafnium precursor, a zirconium precursor, a first dopant precursor, and a second dopant precursor.
